(19) United States
(12) Patent Application Publication
(10) Pub. No.: US 2025/0274089 A1
(43) Pub. Date: Aug. 28, 2025

(54) AMPLIFIER CIRCUIT AND CURRENT BUFFER THEREOF

(71) Applicant: Richtek Technology Corporation, Zhubei City (TW)

(72) Inventor: Min-Hung Hu, New Taipei (TW)

(21) Appl. No.: 18/673,588

(22) Filed: May 24, 2024

(30) Foreign Application Priority Data
Feb. 23, 2024 (TW) 113106632

(51) Int. Cl. H03F 3/45

(52) U.S. Cl. CPC H03F 3/45273; H03F 3/45757; H03F 2200/151

(57) ABSTRACT

A current buffer includes: a current replication circuit for generating a first intermediate current at a first node and a second intermediate current at a second node according to an input current; a first impedance biasing circuit for providing a first input impedance at the first node and generating an output current according to a current flowing through the first node; a second impedance biasing circuit for providing a second input impedance at the second node; and a feedforward capacitor coupled between the first node and the second node. The first input impedance is lower than the second input impedance, such that a current gain between the output current and the input current has a zero and a pole which are related to the feedforward capacitor and the second input impedance. The zero has a lower frequency than the pole.

### CROSS REFERENCE

The present invention claims priority to the TW patent application Ser. No. 113106632, filed on Feb. 23, 2024.

### BACKGROUND OF THE PRESENT INVENTION

### Field of Invention

The present invention relates to an amplifier circuit and a current buffer therein, and particularly to an amplifier circuit and its current buffer capable of generating one or more independently adjustable zeros.

### Description of Related Art

FIG. 1 shows a conventional voltage regulator circuit. FIG. 2 is a transient waveform diagram corresponding to FIG. 1. Traditional voltage regulator circuits, such as linear voltage regulators, are usually designed to parallel a feedforward capacitor CFF with the voltage-dividing resistors R1 and R2 in the feedback path. This feedforward path introduces an additional zero in the feedback gain, allowing for improved loop bandwidth, phase margin (PM), and power supply rejection ratio (PSRR) by designing the location of this zero. Slight differences in frequency response between the output voltage VOUT and the feedback signal VFB can be amplified during large signal behaviors such as step response because of the accumulation of small signal. Therefore, during reference tracking operations like soft start, only the feedback signal VFB tracks the reference while the output voltage VOUT significantly lags, meaning the feedback signal VFB does not accurately reflect the state of the output voltage VOUT to the error amplifier 103, losing proper control over the output voltage VOUT, as shown in the left diagram of FIG. 2 (with CFF).

Moreover, in the prior art, when the feedback gain is 1, meaning R2 is 0, it's impossible to improve the frequency response by setting the aforementioned feedforward capacitor in the feedback path.

In view of the above deficiencies of the prior art, the present invention proposes an amplifier circuit and a current buffer therein, which can freely design the location of the zeros as needed for frequency compensation and can be applied to amplifier circuits with a feedback gain of 1.

### SUMMARY OF THE PRESENT INVENTION

In one aspect, the present invention provides a current buffer including: a current replication circuit configured to operably generate a first intermediate current at a first node and a second intermediate current at a second node according to an input current; a first impedance biasing circuit coupled to the first node and configured to operably provide a first input impedance at the first node and generate an output current according to a current flowing through the first node; a second impedance biasing circuit coupled to the second node and configured to operably provide a second input impedance at the second node; and a first feedforward capacitor coupled between the first node and the second node; wherein the first input impedance is lower than the second input impedance, such that a current gain between the output current and the input current has a first zero and a first pole, wherein a first zero frequency of the first zero is lower than a first pole frequency of the first pole, wherein the first zero frequency and/or the first pole frequency is correlated with a capacitance value of the first feedforward capacitor and an impedance value of the second input impedance.

In one embodiment, when a frequency of the input current is significantly lower than the first zero frequency, the current gain is correlated with a ratio of the first intermediate current to the input current, wherein when the frequency of the input current is significantly higher than the first pole frequency, the current gain is correlated with a ratio of a linear superposition of the second intermediate current over the first intermediate current to the input current.

In one embodiment, a ratio of the first pole frequency to the first zero frequency is correlated with a ratio of a current sum to the first intermediate current, wherein the current sum is a sum of the first intermediate current and the second intermediate current.

In one embodiment, the capacitance value of the first feedforward capacitor is significantly larger than an equivalent capacitance value at the first node, and the capacitance value of the first feedforward capacitor is significantly larger than an equivalent capacitance value at the second node, such that the ratio of the first pole frequency to the first zero frequency is correlated with the ratio of the current sum to the first intermediate current.

In one embodiment, a unity gain bandwidth of the second impedance biasing circuit is larger than a unity gain bandwidth of the first impedance biasing circuit to an extent such that the ratio of the first pole frequency to the first zero frequency is correlated with the ratio of the current sum to the first intermediate current.

In one embodiment, the current buffer further includes: a third impedance biasing circuit coupled to a third node and configured to operably provide a third input impedance at the third node; and a second feedforward capacitor coupled between the first node and the third node; wherein the first input impedance is less than the third input impedance, such that the current gain between the output current and the input current has a second zero and a second pole, wherein a second zero frequency of the second zero is lower than a second pole frequency of the second pole, wherein the second zero frequency and/or the second pole frequency is correlated with a capacitance value of the second feedforward capacitor and an impedance value of the third input impedance.

In one embodiment, the current replication circuit is a current mirror configured to operably mirror the input current to generate the first intermediate current and the second intermediate current.

In one embodiment, the current replication circuit is a current buffer circuit configured to operably buffer the input current through at least one buffer transistor to generate the first intermediate current, and to operably mirror the input current to generate the second intermediate current.

In one embodiment, at least one of the first impedance biasing circuit and the second impedance biasing circuit is a voltage regulator circuit, wherein the corresponding first node or second node is a regulation node, wherein the voltage regulator circuit is configured to operably regulate a voltage at the regulation node to a target voltage according to a bias voltage.

In one embodiment, the voltage regulator circuit is a common-gate amplifier stage circuit or a diode-connected transistor.

In one embodiment, the voltage regulator circuit includes an error amplifier and an impedance control transistor, wherein the error amplifier is configured to operably amplify a difference between the voltage at the regulation node and the bias voltage to generate an error amplification signal, so as to control the impedance control transistor, and to regulate the voltage at the regulation node to the target voltage.

In one embodiment, the current replication circuit includes a first compensation capacitor and a second compensation capacitor, wherein the first compensation capacitor is coupled between an input node and the first node, wherein the second compensation capacitor is coupled between the input node and the second node, wherein the first compensation capacitor and the second compensation capacitor generate the input current at the input node according to an input voltage at the input node, wherein the first compensation capacitor generates the first intermediate current at the first node according to the input voltage, wherein the second compensation capacitor generates the second intermediate current at the second node according to the input voltage.

In one embodiment, the current buffer is for use in an amplifier circuit, wherein the amplifier circuit is configured to operably amplify an intermediate amplification signal at an intermediate node within the amplifier circuit to generate an amplified output signal at an amplification output terminal of the amplifier circuit, wherein an absolute value of a gain between the amplified output signal and the intermediate amplification signal is larger than 1; wherein the amplification output terminal is coupled to the input node of the current buffer, the amplified output signal corresponds to the input voltage of the current buffer, the intermediate node is coupled to the first node of the current buffer, the intermediate amplification signal is generated according to the output current of the current buffer, thereby the current buffer is configured as Miller compensation for the amplifier circuit, and the first zero of the current buffer is configured to compensate for at least one pole of the amplifier circuit, such that the amplifier circuit has sufficient phase margin.

In another aspect, the present invention provides an amplifier circuit comprising: a pre-amplification circuit and an output stage circuit, wherein the pre-amplification circuit is configured to operably amplify a differential input signal to generate a pre-amplification signal, wherein the output stage circuit is configured to operably generate a post-amplification signal according to the pre-amplification signal, wherein the output stage circuit includes a current buffer, wherein an input current of the current buffer is generated according to the pre-amplification signal, and the post-amplification signal corresponds to an output current of the current buffer; or, the amplifier circuit includes: a pre-amplification circuit, an intermediate amplification circuit and an output stage circuit, wherein the pre-amplification circuit is configured to operably amplify a differential input signal to generate a pre-amplification signal, wherein the intermediate amplification circuit is configured to operably amplify the pre-amplification signal to generate an intermediate amplification signal, wherein the output stage circuit is configured to operably generates a post-amplification signal according to the intermediate amplification signal, wherein the intermediate amplification circuit includes the current buffer, wherein the input current of the current buffer is generated according to the pre-amplification signal, wherein the intermediate amplification signal is generated according to the output current of the current buffer; wherein the current buffer includes: a current replication circuit configured to operably generate a first intermediate current at a first node and a second intermediate current at a second node according to the input current; a first impedance biasing circuit coupled to the first node and configured to operably provide a first input impedance at the first node and generate the output current according to a current flowing through the first node; a second impedance biasing circuit coupled to the second node and configured to operably provide a second input impedance at the second node; and a first feedforward capacitor coupled between the first node and the second node; wherein the first input impedance is lower than the second input impedance, such that a current gain between the output current and the input current has a first zero and a first pole, wherein a first zero frequency of the first zero is lower than a first pole frequency of the first pole, wherein the first zero frequency and/or the first pole frequency is correlated with a capacitance value of the first feedforward capacitor and an impedance value of the second input impedance.

In still another aspect, the present invention provides an amplifier circuit comprising: a pre-amplification circuit and an output stage circuit, wherein the pre-amplification circuit is configured to operably amplify a differential input signal to generate a pre-amplification signal, wherein the output stage circuit is configured to operably generate a post-amplification signal according to the pre-amplification signal, wherein the output stage circuit includes a current buffer, wherein an input current of the current buffer is generated according to the pre-amplification signal, and the post-amplification signal corresponds to an output current of the current buffer; or, the amplifier circuit includes: a pre-amplification circuit, an intermediate amplification circuit and an output stage circuit, wherein the pre-amplification circuit is configured to operably amplify a differential input signal to generate a pre-amplification signal, wherein the intermediate amplification circuit is configured to operably amplify the pre-amplification signal to generate an intermediate amplification signal, wherein the output stage circuit is configured to operably generates a post-amplification signal according to the intermediate amplification signal, wherein the intermediate amplification circuit includes the current buffer, wherein the input current of the current buffer is generated according to the pre-amplification signal, wherein the intermediate amplification signal is generated according to the output current of the current buffer; wherein the amplifier circuit further includes a feedback circuit configured to operably generate a feedback signal according to the post-amplification signal, wherein the differential input signal corresponds to a difference between the feedback signal and a reference signal, wherein the amplifier circuit regulates the post-amplification signal to a target level according to the feedback signal, the target level is correlated with the reference signal; wherein the current buffer includes: a current replication circuit configured to operably generate a first intermediate current at a first node and a second intermediate current at a second node according to the input current; a first impedance biasing circuit coupled to the first node and configured to operably provide a first input impedance at the first node and generate the output current according to a current flowing through the first node; a second impedance biasing circuit coupled to the second node and configured to operably provide a second input impedance at the second node; and a first feedforward capacitor coupled between the first node and the second node; wherein the first input impedance is lower than the second input impedance, such that a current gain between the output current and the input current has a first zero and a first pole, wherein a first zero frequency of the first zero is lower than a first pole frequency of the first pole, wherein the first zero frequency and/or the first pole frequency is correlated with a capacitance value of the first feedforward capacitor and an impedance value of the second input impedance.

The advantages of the present invention are that the present invention can achieve zeros while loosening the relationship between the zeros and the resistors, can generate one or more independently adjustable zeros, can perform improved adjustments of loop bandwidth, phase margin (PM), and power supply rejection ratio (PSRR), can offer load tracking capabilities, can be broadly applied in various fundamental analog circuits, and can address issues related to feedback signal distortion during large signal operations.

This document has detailed the present invention through specific embodiments. However, these descriptions are intended to facilitate understanding of the present invention's objectives, technical contents, features, and achieved effects, rather than to limit the scope of the present invention. Various combinations and equivalent variations, under the spirit of the present invention, can be conceived by those skilled in the art without departing from the scope and spirit of the present invention.

### BRIEF DESCRIPTION OF THE DRAWINGS

FIG. 1 depicts a conventional voltage regulator circuit.

FIG. 2 shows transient waveform diagrams corresponding to FIG. 1.

FIGS. 3A and 3B illustrate loop block diagrams of an amplifier circuit according to embodiments of the present invention.

FIG. 4A illustrates a circuit block diagram of a current buffer according to one embodiment of the present invention.

FIG. 4B illustrates the frequency response of the current gain for the current buffer according to one embodiment of the present invention.

FIG. 5 illustrates a circuit block diagram of a current buffer according to another embodiment of the present invention.

FIG. 6A illustrates a circuit schematic diagram of a current buffer according to one embodiment of the present invention.

FIG. 6B illustrates a circuit schematic diagram of a current buffer according to another embodiment of the present invention.

FIG. 7 illustrates a circuit block diagram of an impedance biasing circuit of a current buffer according to one embodiment of the present invention.

FIG. 8 illustrates a circuit schematic diagram of a current buffer according to another embodiment of the present invention.

FIG. 9 illustrates a circuit schematic diagram of a current buffer according to still another embodiment of the present invention.

FIG. 10 illustrates a circuit schematic diagram of a current buffer according to yet another embodiment of the present invention.

FIG. 11 illustrates a circuit schematic diagram of a current buffer according to still another embodiment of the present invention.

FIG. 12 illustrates a circuit schematic diagram of a current buffer according to yet another embodiment of the present invention.

FIG. 13 illustrates a circuit schematic diagram of an amplifier circuit according to one embodiment of the present invention.

FIG. 14 illustrates a circuit schematic diagram of an amplifier circuit according to another embodiment of the present invention.

FIG. 15 illustrates a circuit schematic diagram of an amplifier circuit according to still another embodiment of the present invention.

FIG. 16 illustrates a circuit schematic diagram of a current buffer according to yet another embodiment of the present invention.

FIG. 17 illustrates a circuit schematic diagram of an amplifier circuit according to still another embodiment of the present invention.

FIG. 18A illustrates a graph showing the open-loop gain frequency response corresponding to FIG. 15, according to one embodiment of the present invention.

FIG. 18B illustrates a graph showing the open-loop phase frequency response corresponding to FIG. 15, according to one embodiment of the present invention.

FIG. 18C illustrates a graph showing the transient response in output current corresponding to FIG. 15, according to one embodiment of the present invention.

FIG. 18D illustrates a graph showing the load transient response of the output voltage corresponding to FIG. 15, according to one embodiment of the present invention.

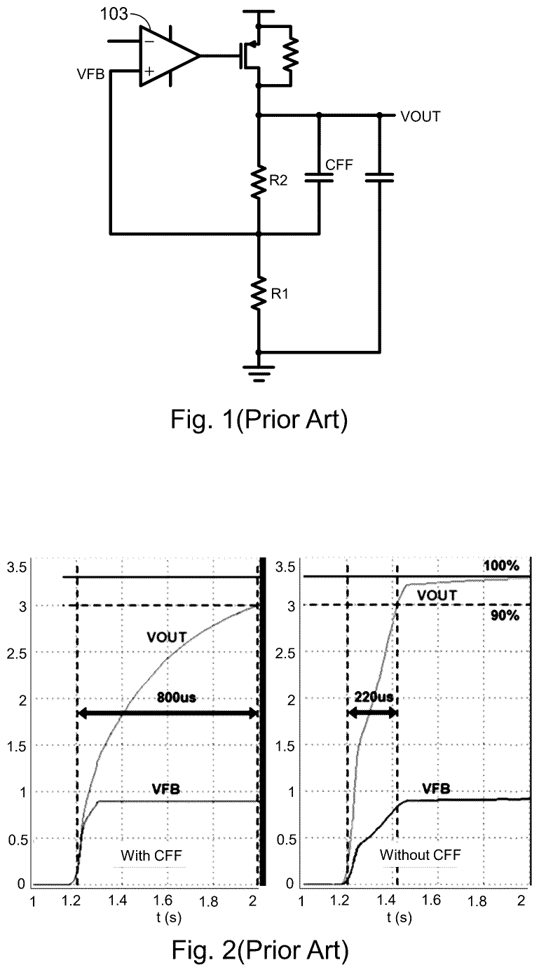

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

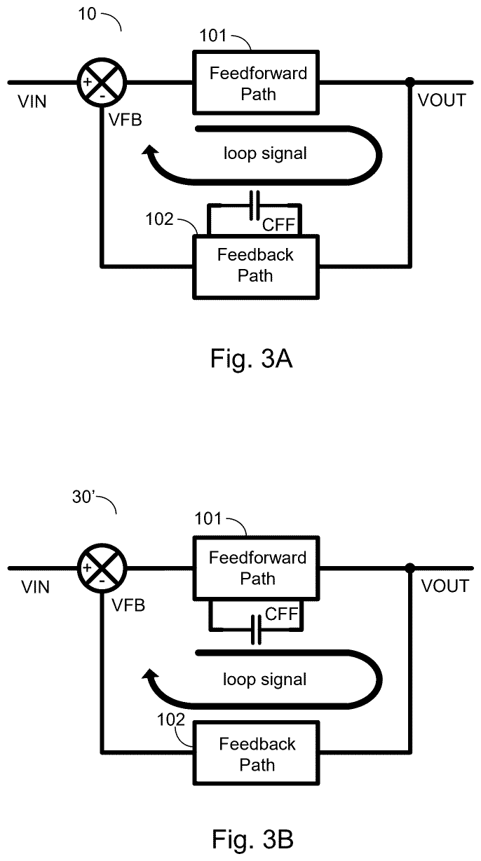

FIGS. 3A and 3B illustrate loop block diagrams of an amplifier circuit according to embodiments of the present invention. As shown in FIG. 3A, a capacitor CFF of an amplifier circuit 10 can be disposed on a feedback path 102. As shown in FIG. 3B, in one embodiment of the present invention, the feedforward capacitor CFF of the amplifier circuit 30′ can alternatively be configured on the feedforward path 101. Preferably, when the feedforward capacitor CFF is disposed on the feedforward path 101, it is unaffected by the feedback gain and its impedance value.

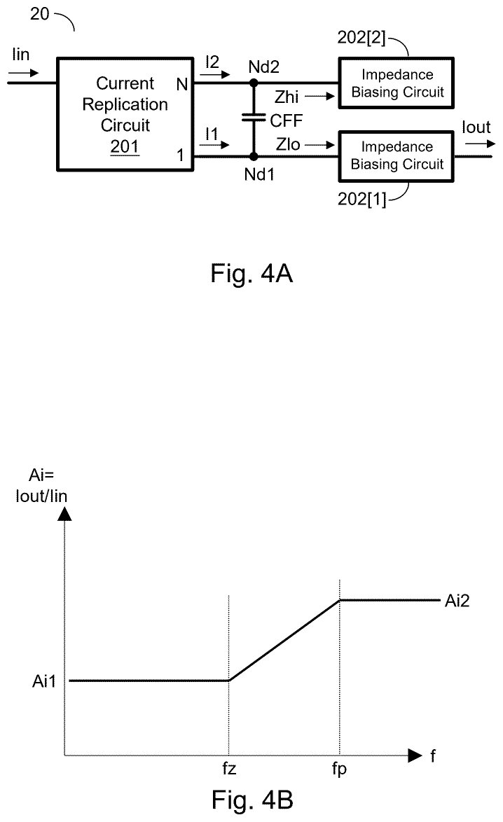

FIG. 4A illustrates a circuit block diagram of a current buffer according to one embodiment of the present invention. The current buffer 20 of the present invention includes a current replication circuit 201, impedance biasing circuits 202[1] and 202[2], and a feedforward capacitor CFF. The current replication circuit 201 is configured to generate an intermediate current I1 at the first node Nd1 and an intermediate current I2 at the second node Nd2 according to the input current Iin, where both intermediate currents I1 and I2 are linearly related (e.g., proportional) to the input current Iin. The impedance biasing circuit 202[1], coupled to the first node Nd1, is configured to provide a first input impedance Zlo at the first node Nd1 and to generate an output current Iout according to the current flowing through the first node Nd1. The impedance biasing circuit 202[2], coupled to the second node Nd2, is configured to provide a second input impedance Zhi at the second node Nd2. The feedforward capacitor CFF is coupled between the first node Nd1 and the second node Nd2. The first input impedance Zlo is less than the second input impedance Zhi, such that the current gain Ai between the output current Iout and the input current Iin has a first zero and a first pole. In one embodiment, the ratio of the intermediate current I2 to the intermediate current I1 is N:1.

FIG. 4B illustrates the frequency response of the current gain for the current buffer according to one embodiment of the present invention. As shown in FIG. 4B, the first zero frequency fz of the first zero is less than the first pole frequency fp of the first pole. In one embodiment, the first zero frequency fz and/or the first pole frequency fp is correlated with the capacitance value of the feedforward capacitor CFF and the impedance value of the second input impedance Zhi. In one embodiment, the capacitance value of the feedforward capacitor CFF is much larger than the equivalent capacitance value at the first node Nd1, and the capacitance value of the feedforward capacitor CFF is much larger than the equivalent capacitance value at the second node Nd2 to an extent that the ratio of the first pole frequency fp to the first zero frequency fz is correlated with the ratio of a current sum to the intermediate current I1, wherein the current sum is the sum of the intermediate currents I1 and I2. In one embodiment, the ratio of the first pole frequency fp to the first zero frequency fz is approximately equal to the ratio of the current sum to the intermediate current I1. In other words, corresponding to the embodiment shown in FIG. 4A, the ratio of the first pole frequency fp to the first zero frequency fz is approximately equal to (N+1):1, that is, N+1.

Moreover, the unity gain bandwidth of the impedance biasing circuit also affects the aforementioned ratio of the first pole frequency fp to the first zero frequency fz. In one embodiment, the unity gain bandwidth of the impedance biasing circuit 202[2] is larger than that of the impedance biasing circuit 202[1] to an extent that the ratio of the first pole frequency fp to the first zero frequency fz is correlated with the ratio of the current sum to the intermediate current I1, for example, close to N+1.

As shown in FIG. 4B, when the frequency of the input current Iin is much lower than the first zero frequency fz, the level Aul of the current gain Ai is correlated with the ratio of the intermediate current I1 to the input current Iin, and when the frequency of the input current Iin is much higher than the first pole frequency fp, the level Ai2 of the current gain Ai is correlated with the ratio of the linear superposition value of the intermediate current I2 over the intermediate current I1 to the input current Iin. In one preferred embodiment, when the ratio of the first pole frequency fp to the first zero frequency fz is close to N+1 (i.e., when the aforementioned condition is met), Ai2=(N+1)*Ai1.

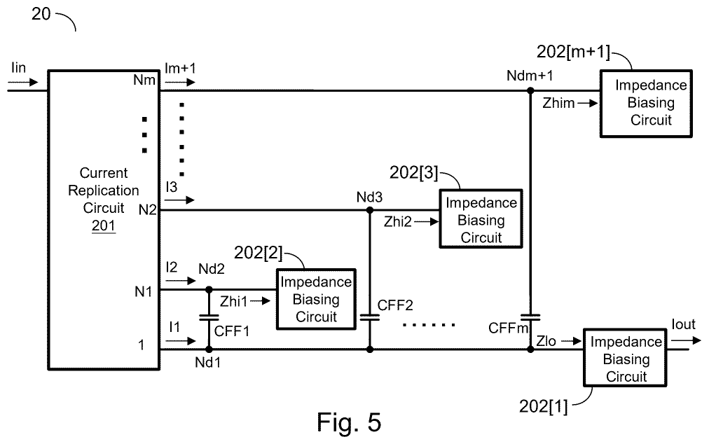

FIG. 5 illustrates a circuit block diagram of a current buffer according to another embodiment of the present invention. The present embodiment is similar to the embodiment shown in FIG. 4A, with the difference being, as illustrated in FIG. 5, that the current buffer 20 further includes impedance biasing circuits 202[3] to 202[m+1] and feedforward capacitors CFF2 to CFFm, wherein m is a positive integer larger than 2. The impedance biasing circuit 202[3] is coupled to the third node Nd3 and is configured to provide a third input impedance Zhi2 at the third node Nd3. Similarly, the impedance biasing circuit 202[m+1] is coupled to the (m+1)th node Ndm+1 and is configured to provide the (m+1)th input impedance Zhim at the (m+1)th node Ndm+1. The feedforward capacitor CFF2 is coupled between the first node Nd1 and the third node Nd3. Similarly, the feedforward capacitor CFFm is coupled between the first node Nd1 and the (m+1)th node Ndm+1. The first input impedance Zlo is less than the third input impedance Zhi2, such that the current gain Ai between the output current Iout and the input current Iin has a second zero and a second pole, wherein the second zero frequency of the second zero is less than the second pole frequency of the second pole, wherein the second zero frequency and/or the second pole frequency is correlated with the capacitance value of the feedforward capacitor CFF2 and the impedance value of the third input impedance Zhi2. Similarly, the first input impedance Zlo is less than the (m+1)th input impedance Zhim, such that the current gain Ai between the output current Iout and the input current Iin has an mth zero and an mth pole, wherein the mth zero frequency of the mth zero is less than the mth pole frequency of the mth pole, wherein the mth zero frequency and/or the mth pole frequency is correlated with the capacitance value of the feedforward capacitor CFFm and the impedance value of the (m+1)th input impedance Zhim.

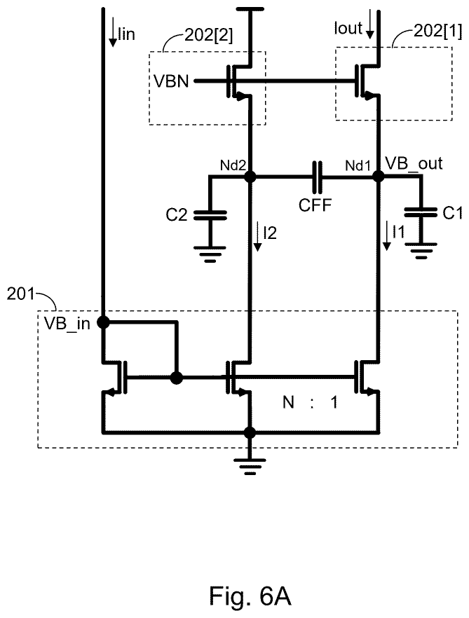

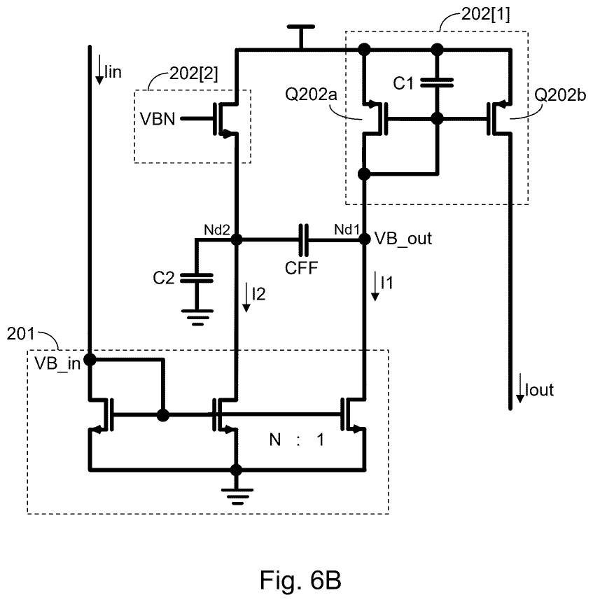

FIG. 6A illustrates a circuit schematic diagram of a current buffer according to one embodiment of the present invention. The present embodiment is a specific embodiment which corresponds to the embodiment shown in FIG. 4A. In the present embodiment, the current replication circuit 201 is a current mirror configured to mirror the input current Iin to generate the intermediate currents I1 and I2. The impedance biasing circuits 202[1] and 202[2] are common-gate amplifier stages. The capacitance value of the feedforward capacitor CFF is much larger than the equivalent capacitance value C1 at the first node Nd1, and the capacitance value of the feedforward capacitor CFF is much larger than the equivalent capacitance value C2 at the second node Nd2.

FIG. 6B illustrates a circuit schematic diagram of a current buffer according to another embodiment of the present invention. The present embodiment is similar to the embodiment shown in FIG. 6A, with the difference being that in the impedance biasing circuit 202[1], the transistor Q202a is a diode-connected transistor, and the transistor Q202b is configured to mirror transistor Q202a to generate the output current Iout.

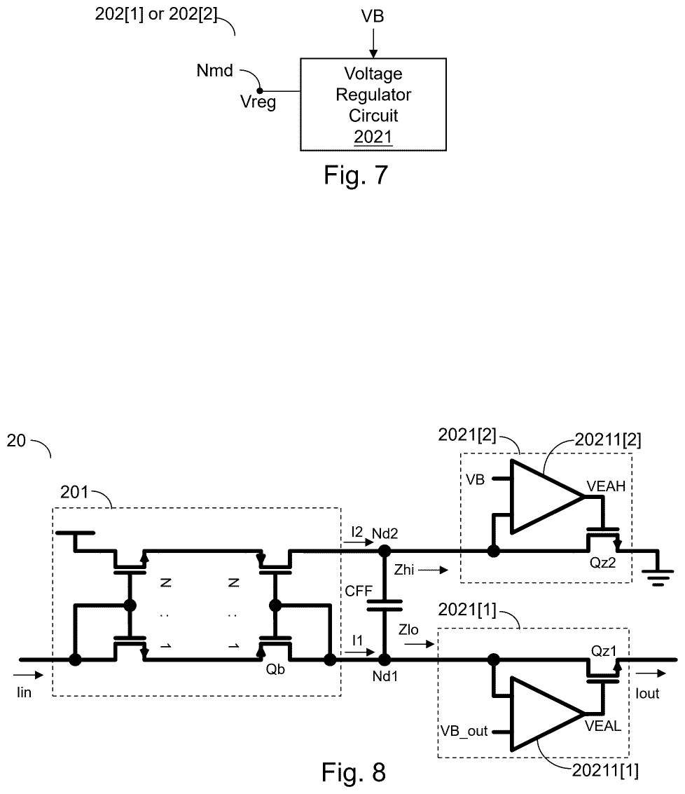

FIG. 7 illustrates a circuit block diagram of an impedance biasing circuit of a current buffer according to one embodiment of the present invention. At least one of the impedance biasing circuits 202[1] and 202[2] corresponds to a voltage regulator circuit 2021. The voltage regulator circuit 2021 is configured to regulate the voltage Vreg at the regulation node Nmd to a target voltage according to the bias voltage VB. The aforementioned corresponding first node Nd1 or second node Nd2 corresponds to the regulation node Nmd.

FIG. 8 illustrates a circuit schematic diagram of a current buffer according to another embodiment of the present invention. The present embodiment is a specific embodiment which corresponds to the embodiment shown in FIG. 4A. In the present embodiment, the current replication circuit 201 is a current buffer circuit configured to buffer the input current Iin through at least one buffer transistor (e.g., Qb) to generate the intermediate current I1, and to mirror the input current Iin to generate the intermediate current I2. The voltage regulator circuits 2021[1] and 2021[2] include error amplifiers 20211[1] and 20211[2] and impedance control transistors Qz1 and Qz2, respectively. The error amplifier 20211[1] is configured to amplify the difference between the voltage at the first node Nd1 and the bias voltage VB to generate an error amplification signal VEAH, so as to control the impedance control transistor Qz1, such that the voltage at the first node Nd1 can be regulated to the target voltage (in the present embodiment, VB). The error amplifier 20211[2] is configured to amplify the difference between the voltage at the second node Nd2 and the bias voltage VB_out to generate an error amplification signal VEAL, so as to control the impedance control transistor Qz2, such that the voltage at the second node Nd2 can be regulated to the target voltage (in the present embodiment, VB_out).

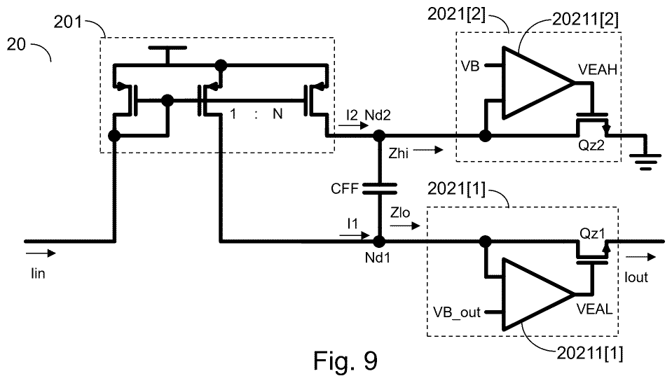

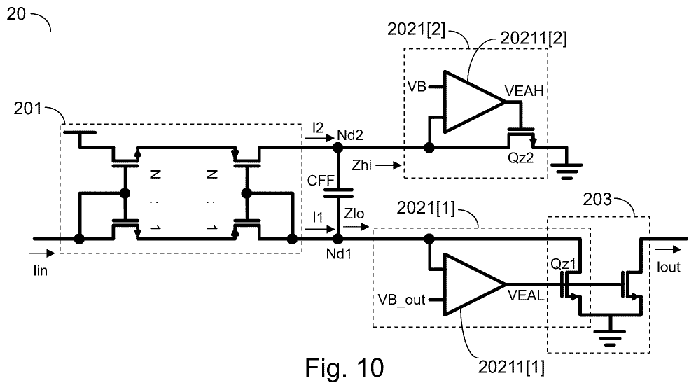

FIG. 9 illustrates a circuit schematic diagram of a current buffer according to still another embodiment of the present invention. The present embodiment is similar to the embodiment shown in FIG. 8, with the difference being that the current replication circuit 201 in FIG. 9 is a current mirror configured to mirror the input current Iin to generate the intermediate currents I1 and I2. FIG. 10 illustrates a circuit schematic diagram of a current buffer according to yet another embodiment of the present invention. The present embodiment is similar to the embodiment shown in FIG. 8, with the difference being that the current buffer 20 in FIG. 10 further includes a current mirror 203 configured to mirror the intermediate current I1 to generate the output current Iout.

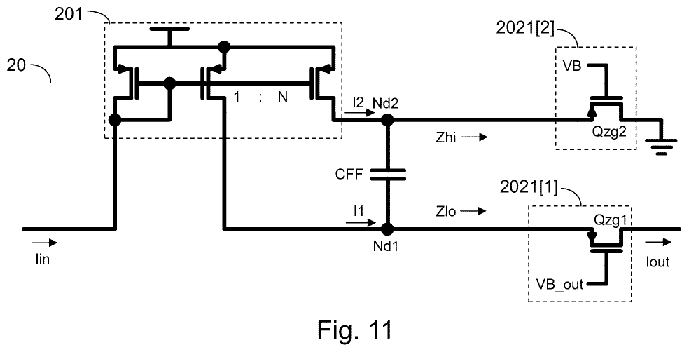

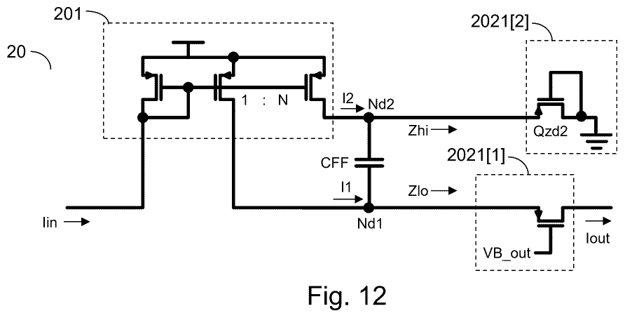

FIG. 11 illustrates a circuit schematic diagram of a current buffer according to still another embodiment of the present invention. The present embodiment is similar to the embodiment shown in FIG. 9, with the difference being that the voltage regulator circuits 2021[1] and 2021[2] in FIG. 11 are common-gate amplifier stages. Specifically, the voltage regulator circuits 2021[1] and 2021[2] include common-gate transistors Qzg1 and Qzg2, respectively. The gates of common-gate transistors Qzg1 and Qzg2 are biased by the bias voltages VB and VB_out, respectively. The voltage at the first node Nd1 is regulated to the absolute value of the bias voltage VB_out plus the conduction threshold voltage of the common-gate transistor Qzg1, while the voltage at the second node Nd2 is regulated to the absolute value of the bias voltage VB plus the conduction threshold voltage of the common-gate transistor Qzg2. FIG. 12 illustrates a circuit schematic diagram of a current buffer according to yet another embodiment of the present invention. The present embodiment is similar to the embodiment shown in FIG. 11, with the difference being that the voltage regulator circuit 2021[2] in FIG. 12 includes a diode-connected transistor Qzd2.

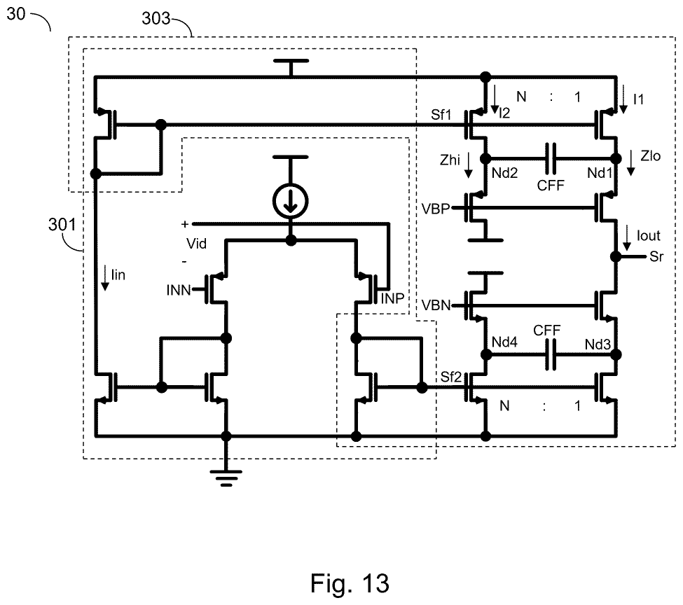

FIG. 13 illustrates a circuit schematic diagram of an amplifier circuit according to one embodiment of the present invention. As shown in FIG. 13, the amplifier circuit 30 includes a pre-amplification circuit 301 and an output stage circuit 303. The pre-amplification circuit 301 is configured to amplify a differential input signal Vid to generate pre-amplification signals Sf1 and Sf2, while the output stage circuit 303 is configured to generate a post-amplification signal Sr according to the pre-amplification signals Sf1 and Sf2. In the present embodiment, the output stage circuit 303 includes the current buffer corresponding to FIG. 11. In other embodiments, the output stage circuit 303 may also include the current buffer corresponding to any of FIGS. 4A, 5, 6A, 6B, 7-10, and I2. The input current Iin of the current buffer 20 is generated according to the pre-amplification signals Sf1 and Sf2, and the post-amplification signal Sr corresponds to the output current Iout of the current buffer 20.

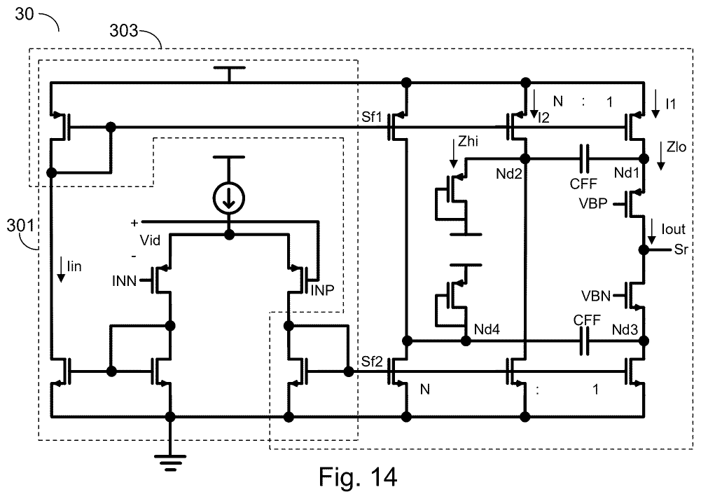

FIG. 14 illustrates a circuit schematic diagram of an amplifier circuit according to another embodiment of the present invention. As shown in FIG. 14, the amplifier circuit 30 includes a pre-amplification circuit 301 and an output stage circuit 303. The pre-amplification circuit 301 is configured to amplify a differential input signal Vid to generate pre-amplification signals Sf1 and Sf2, while the output stage circuit 303 is configured to generate a post-amplification signal Sr according to the pre-amplification signals Sf1 and Sf2. In the present embodiment, the output stage circuit 303 includes the current buffer corresponding to FIG. 12.

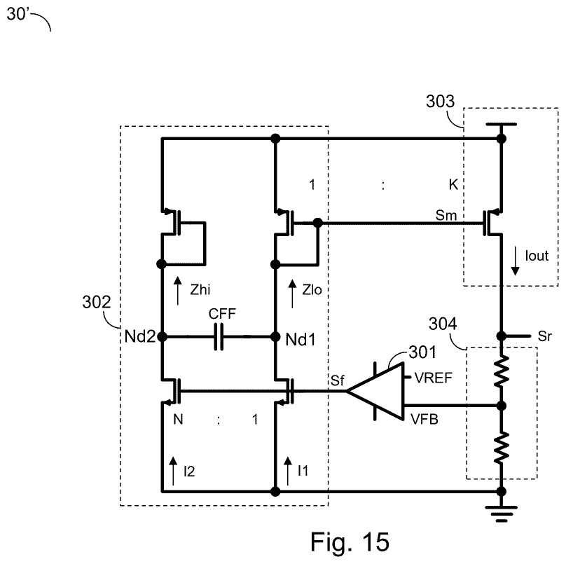

FIG. 15 illustrates a circuit schematic diagram of an amplifier circuit according to still another embodiment of the present invention. As shown in FIG. 15, the amplifier circuit 30′ includes a pre-amplification circuit 301, an intermediate amplification circuit 302, an output stage circuit 303, and a feedback circuit 304. The pre-amplification circuit 301 is configured to amplify a differential input signal to generate a pre-amplification signal Sf, while the intermediate amplification circuit 302 is configured to amplify the pre-amplification signal Sf to generate an intermediate amplification signal Sm. The output stage circuit 303 is configured to generate a post-amplification signal Sr according to the intermediate amplification signal Sm. The feedback circuit 304 is configured to generate a feedback signal VFB according to the post-amplification signal Sr. The differential input signal corresponds to the difference between the feedback signal VFB and a reference signal VREF. The amplifier circuit 30′ regulates the post-amplification signal Sr to a target level according to the feedback signal VFB. The target level is correlated with the reference signal VREF. The intermediate amplification circuit 302 can include the current buffer corresponding to any of FIGS. 4A, 5, 6A, 6B, 7-12. Specifically, in the present embodiment, the intermediate amplification circuit 302 includes the current buffer corresponding to FIG. 12. The input current Iin of the current buffer 20 is generated according to the pre-amplification signal Sf, and the intermediate amplification signal Sm is generated according to the output current Iout of the current buffer 20.

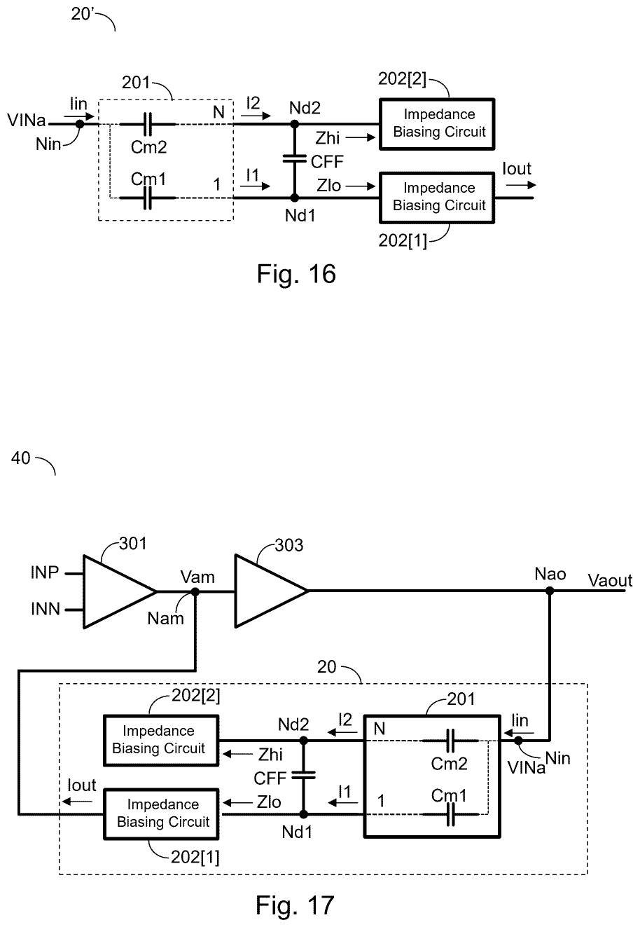

FIG. 16 illustrates a circuit schematic diagram of a current buffer according to yet another embodiment of the present invention (current buffer 20′). The present embodiment is similar to the embodiment shown in FIG. 4A, with the difference being that the current replication circuit 201 includes compensation capacitors Cm1 and Cm2. The compensation capacitor Cm1 is coupled between the input node Nin and the first node Nd1, while the compensation capacitor Cm2 is coupled between the input node Nin and the second node Nd2. The compensation capacitors Cm1 and Cm2 generate the input current Iin at the input node Nin according to the input voltage VINa at the input node Nin. The compensation capacitor Cm1 generates the intermediate current I1 at the first node Nd1 according to the input voltage VINa, and the compensation capacitor Cm2 generates the intermediate current I2 at the second node Nd2 according to the input voltage VINa.

FIG. 17 illustrates a circuit schematic diagram of an amplifier circuit according to still another embodiment of the present invention. As shown in FIG. 17, the amplifier circuit 40 includes a differential amplification stage circuit 301, a gain amplification stage circuit 303, and the current buffer 20′. The differential amplification stage circuit 301 is configured to amplify the difference between the non-inverting input signal and the inverting input signal to generate an intermediate amplification signal Vam at the intermediate node Nam. The gain amplification stage circuit 303 is configured to amplify the intermediate amplification signal Vam to generate an amplified output signal Vaout at the amplification output terminal Nao of the amplifier circuit 40. In one embodiment, the gain amplification stage circuit 303 is an inverting amplifier stage, with the amplified output signal Vaout having an absolute gain value larger than 1 relative to the intermediate amplification signal Vam. The amplification output terminal Nao is coupled to the input node Nin of the current buffer 20′, with the amplification output signal Vaout corresponding to the input voltage VINa of the current buffer 20′. The intermediate node Nam is coupled to the first node Nd1 of the current buffer 20′ through the impedance biasing circuit 202[1], with the intermediate amplification signal Vam being generated according to the output current Iout of the current buffer 20′.

In the present embodiment, the compensation capacitors Cm1 and Cm2 of the current buffer 20′ firstly provide the function of a Miller compensation capacitor, and furthermore, the first zero of the current buffer 20′ is configured to compensate for at least one pole of the amplifier circuit 40, such that the amplifier circuit 40 has sufficient phase margin. The at least one pole can be, for example, a pole generated by the differential amplification stage circuit 301 or the gain amplification stage circuit 303 before compensation.

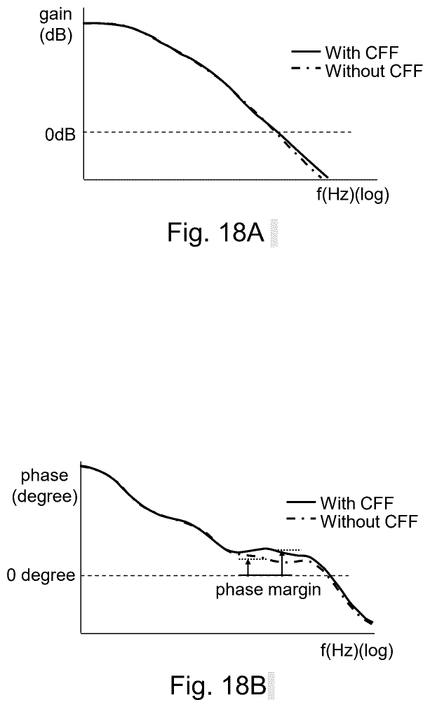

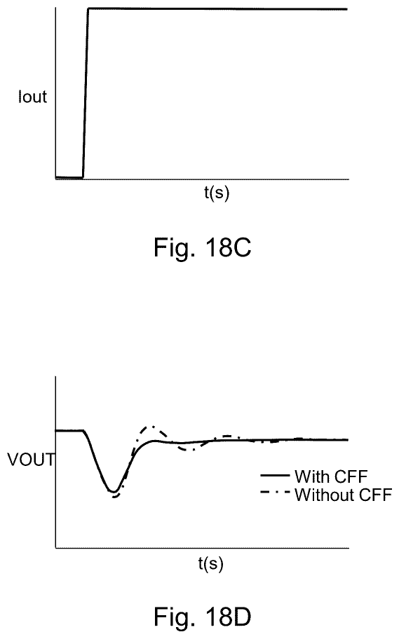

FIG. 18A illustrates a graph showing the open-loop gain frequency response corresponding to FIG. 15, according to one embodiment of the present invention. The gain with and without the feedforward capacitor CFF is shown in FIG. 18A.

FIG. 18B illustrates a graph showing the open-loop phase frequency response corresponding to FIG. 15, according to one embodiment of the present invention. The phase with and without the feedforward capacitor CFF is shown in FIG. 18B, where a larger phase margin can be achieved with the feedforward capacitor CFF.

FIG. 18C illustrates a graph showing the transient change in output current corresponding to FIG. 15, according to one embodiment of the present invention.

FIG. 18D illustrates a graph showing the transient response of the output voltage load corresponding to FIG. 15, according to one embodiment of the present invention. The output voltage VOUT with and without the feedforward capacitor CFF is shown in FIG. 18D. In the case of having the feedforward capacitor CFF, better transient response is achieved due to having larger phase margin.

The present invention achieves the realization of zeros while relaxing the relationship between the zeros and resistors, enabling the generation of one or multiple zeros whose locations can be independently adjusted. This capability allows for superior adjustments to frequency response characteristics such as loop bandwidth, PM (Phase Margin), and PSRR (Power Supply Rejection Ratio), and the generated zeros can achieve load tracking effects. This can be widely applied to various basic analog circuits and can also prevent problems caused by feedback signal distortion during large signal operations.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A current buffer comprising:
a current replication circuit configured to operably generate a first intermediate current at a first node and a second intermediate current at a second node according to an input current;
a first impedance biasing circuit coupled to the first node and configured to operably provide a first input impedance at the first node and generate an output current according to a current flowing through the first node;
a second impedance biasing circuit coupled to the second node and configured to operably provide a second input impedance at the second node; and
a first feedforward capacitor coupled between the first node and the second node;
wherein the first input impedance is lower than the second input impedance, such that a current gain between the output current and the input current has a first zero and a first pole, wherein a first zero frequency of the first zero is lower than a first pole frequency of the first pole, wherein the first zero frequency and/or the first pole frequency is correlated with a capacitance value of the first feedforward capacitor and an impedance value of the second input impedance.

2. The current buffer of claim 1, wherein when a frequency of the input current is significantly lower than the first zero frequency, the current gain is correlated with a ratio of the first intermediate current to the input current, wherein when the frequency of the input current is significantly higher than the first pole frequency, the current gain is correlated with a ratio of a linear superposition of the second intermediate current over the first intermediate current to the input current.

3. The current buffer of claim 2, wherein a ratio of the first pole frequency to the first zero frequency is correlated with a ratio of a current sum to the first intermediate current, wherein the current sum is a sum of the first intermediate current and the second intermediate current.

4. The current buffer of claim 3, wherein the capacitance value of the first feedforward capacitor is significantly larger than an equivalent capacitance value at the first node, and the capacitance value of the first feedforward capacitor is significantly larger than an equivalent capacitance value at the second node, such that the ratio of the first pole frequency to the first zero frequency is correlated with the ratio of the current sum to the first intermediate current.

5. The current buffer of claim 3, wherein a unity gain bandwidth of the second impedance biasing circuit is larger than a unity gain bandwidth of the first impedance biasing circuit to an extent such that the ratio of the first pole frequency to the first zero frequency is correlated with the ratio of the current sum to the first intermediate current.

6. The current buffer of claim 1, further comprising:
a third impedance biasing circuit coupled to a third node and configured to operably provide a third input impedance at the third node; and
a second feedforward capacitor coupled between the first node and the third node;
wherein the first input impedance is less than the third input impedance, such that the current gain between the output current and the input current has a second zero and a second pole, wherein a second zero frequency of the second zero is lower than a second pole frequency of the second pole, wherein the second zero frequency and/or the second pole frequency is correlated with a capacitance value of the second feedforward capacitor and an impedance value of the third input impedance.

7. The current buffer of claim 1, wherein the current replication circuit is a current mirror configured to operably mirror the input current to generate the first intermediate current and the second intermediate current.

8. The current buffer of claim 1, wherein the current replication circuit is a current buffer circuit configured to operably buffer the input current through at least one buffer transistor to generate the first intermediate current, and to operably mirror the input current to generate the second intermediate current.

9. The current buffer of claim 1, wherein at least one of the first impedance biasing circuit and the second impedance biasing circuit is a voltage regulator circuit, wherein the corresponding first node or second node is a regulation node, wherein the voltage regulator circuit is configured to operably regulate a voltage at the regulation node to a target voltage according to a bias voltage.

10. The current buffer of claim 9, wherein the voltage regulator circuit is a common-gate amplifier stage circuit or a diode-connected transistor.

11. The current buffer of claim 9, wherein the voltage regulator circuit includes an error amplifier and an impedance control transistor, wherein the error amplifier is configured to operably amplify a difference between the voltage at the regulation node and the bias voltage to generate an error amplification signal, so as to control the impedance control transistor, and to regulate the voltage at the regulation node to the target voltage.

12. The current buffer of claim 1, wherein the current replication circuit includes a first compensation capacitor and a second compensation capacitor, wherein the first compensation capacitor is coupled between an input node and the first node, wherein the second compensation capacitor is coupled between the input node and the second node, wherein the first compensation capacitor and the second compensation capacitor generate the input current at the input node according to an input voltage at the input node, wherein the first compensation capacitor generates the first intermediate current at the first node according to the input voltage, wherein the second compensation capacitor generates the second intermediate current at the second node according to the input voltage.

13. The current buffer of claim 12, wherein the current buffer is for use in an amplifier circuit, wherein the amplifier circuit is configured to operably amplify an intermediate amplification signal at an intermediate node within the amplifier circuit to generate an amplified output signal at an amplification output terminal of the amplifier circuit, wherein an absolute value of a gain between the amplified output signal and the intermediate amplification signal is larger than 1;
wherein the amplification output terminal is coupled to the input node of the current buffer, the amplified output signal corresponds to the input voltage of the current buffer, the intermediate node is coupled to the first node of the current buffer, the intermediate amplification signal is generated according to the output current of the current buffer, thereby the current buffer is configured as Miller compensation for the amplifier circuit, and the first zero of the current buffer is configured to compensate for at least one pole of the amplifier circuit, such that the amplifier circuit has sufficient phase margin.

14. An amplifier circuit comprising:
a pre-amplification circuit and an output stage circuit, wherein the pre-amplification circuit is configured to operably amplify a differential input signal to generate a pre-amplification signal, wherein the output stage circuit is configured to operably generate a post-amplification signal according to the pre-amplification signal, wherein the output stage circuit includes a current buffer, wherein an input current of the current buffer is generated according to the pre-amplification signal, and the post-amplification signal corresponds to an output current of the current buffer;
or, the amplifier circuit includes:
a pre-amplification circuit, an intermediate amplification circuit and an output stage circuit, wherein the pre-amplification circuit is configured to operably amplify a differential input signal to generate a pre-amplification signal, wherein the intermediate amplification circuit is configured to operably amplify the pre-amplification signal to generate an intermediate amplification signal, wherein the output stage circuit is configured to operably generates a post-amplification signal according to the intermediate amplification signal, wherein the intermediate amplification circuit includes the current buffer, wherein the input current of the current buffer is generated according to the pre-amplification signal, wherein the intermediate amplification signal is generated according to the output current of the current buffer;
wherein the current buffer includes:
a current replication circuit configured to operably generate a first intermediate current at a first node and a second intermediate current at a second node according to the input current;
a first impedance biasing circuit coupled to the first node and configured to operably provide a first input impedance at the first node and generate the output current according to a current flowing through the first node;
a second impedance biasing circuit coupled to the second node and configured to operably provide a second input impedance at the second node; and
a first feedforward capacitor coupled between the first node and the second node;
wherein the first input impedance is lower than the second input impedance, such that a current gain between the output current and the input current has a first zero and a first pole, wherein a first zero frequency of the first zero is lower than a first pole frequency of the first pole, wherein the first zero frequency and/or the first pole frequency is correlated with a capacitance value of the first feedforward capacitor and an impedance value of the second input impedance.

15. An amplifier circuit comprising:
a pre-amplification circuit and an output stage circuit, wherein the pre-amplification circuit is configured to operably amplify a differential input signal to generate a pre-amplification signal, wherein the output stage circuit is configured to operably generate a post-amplification signal according to the pre-amplification signal, wherein the output stage circuit includes a current buffer, wherein an input current of the current buffer is generated according to the pre-amplification signal, and the post-amplification signal corresponds to an output current of the current buffer;
or, the amplifier circuit includes:
a pre-amplification circuit, an intermediate amplification circuit and an output stage circuit, wherein the pre-amplification circuit is configured to operably amplify a differential input signal to generate a pre-amplification signal, wherein the intermediate amplification circuit is configured to operably amplify the pre-amplification signal to generate an intermediate amplification signal, wherein the output stage circuit is configured to operably generates a post-amplification signal according to the intermediate amplification signal, wherein the intermediate amplification circuit includes the current buffer, wherein the input current of the current buffer is generated according to the pre-amplification signal, wherein the intermediate amplification signal is generated according to the output current of the current buffer;
wherein the amplifier circuit further includes a feedback circuit configured to operably generate a feedback signal according to the post-amplification signal, wherein the differential input signal corresponds to a difference between the feedback signal and a reference signal, wherein the amplifier circuit regulates the post-amplification signal to a target level according to the feedback signal, the target level is correlated with the reference signal;
wherein the current buffer includes:
a current replication circuit configured to operably generate a first intermediate current at a first node and a second intermediate current at a second node according to the input current;
a first impedance biasing circuit coupled to the first node and configured to operably provide a first input impedance at the first node and generate the output current according to a current flowing through the first node;
a second impedance biasing circuit coupled to the second node and configured to operably provide a second input impedance at the second node; and
a first feedforward capacitor coupled between the first node and the second node;
wherein the first input impedance is lower than the second input impedance, such that a current gain between the output current and the input current has a first zero and a first pole, wherein a first zero frequency of the first zero is lower than a first pole frequency of the first pole, wherein the first zero frequency and/or the first pole frequency is correlated with a capacitance value of the first feedforward capacitor and an impedance value of the second input impedance.

16. The amplifier circuit of claim 15, wherein when a frequency of the input current is significantly lower than the first zero frequency, the current gain is correlated with a ratio of the first intermediate current to the input current, wherein when the frequency of the input current is significantly higher than the first pole frequency, the current gain is correlated with a ratio of a linear superposition of the second intermediate current over the first intermediate current to the input current.

17. The amplifier circuit of claim 16, wherein a ratio of the first pole frequency to the first zero frequency is correlated with a ratio of a current sum to the first intermediate current, wherein the current sum is a sum of the first intermediate current and the second intermediate current.

18. The amplifier circuit of claim 17, wherein the capacitance value of the first feedforward capacitor is significantly larger than an equivalent capacitance value at the first node, and the capacitance value of the first feedforward capacitor is significantly larger than an equivalent capacitance value at the second node, such that the ratio of the first pole frequency to the first zero frequency is correlated with the ratio of the current sum to the first intermediate current.

19. The amplifier circuit of claim 17, wherein a unity gain bandwidth of the second impedance biasing circuit is larger than a unity gain bandwidth of the first impedance biasing circuit to an extent such that the ratio of the first pole frequency to the first zero frequency is correlated with the ratio of the current sum to the first intermediate current.

20. The amplifier circuit of claim 15, further comprising:
a third impedance biasing circuit coupled to a third node and configured to operably provide a third input impedance at the third node; and
a second feedforward capacitor coupled between the first node and the third node;
wherein the first input impedance is less than the third input impedance, such that the current gain between the output current and the input current has a second zero and a second pole, wherein a second zero frequency of the second zero is lower than a second pole frequency of the second pole, wherein the second zero frequency and/or the second pole frequency is correlated with a capacitance value of the second feedforward capacitor and an impedance value of the third input impedance.

21. The amplifier circuit of claim 15, wherein the current replication circuit is a current mirror configured to operably mirror the input current to generate the first intermediate current and the second intermediate current.

22. The amplifier circuit of claim 15, wherein the current replication circuit is a current buffer circuit configured to operably buffer the input current through at least one buffer transistor to generate the first intermediate current, and to operably mirror the input current to generate the second intermediate current.

23. The amplifier circuit of claim 15, wherein at least one of the first impedance biasing circuit and the second impedance biasing circuit is a voltage regulator circuit, wherein the corresponding first node or second node is a regulation node, wherein the voltage regulator circuit is configured to operably regulate a voltage at the regulation node to a target voltage according to a bias voltage.

24. The amplifier circuit of claim 23, wherein the voltage regulator circuit is a common-gate amplifier stage circuit or a diode-connected transistor.

25. The amplifier circuit of claim 23, wherein the voltage regulator circuit includes an error amplifier and an impedance control transistor, wherein the error amplifier is configured to operably amplify a difference between the voltage at the regulation node and the bias voltage to generate an error amplification signal, so as to control the impedance control transistor, and to regulate the voltage at the regulation node to the target voltage.

26. The amplifier circuit of claim 15, wherein the current replication circuit includes a first compensation capacitor and a second compensation capacitor, wherein the first compensation capacitor is coupled between an input node and the first node, wherein the second compensation capacitor is coupled between the input node and the second node, wherein the first compensation capacitor and the second compensation capacitor generate the input current at the input node according to an input voltage at the input node, wherein the first compensation capacitor generates the first intermediate current at the first node according to the input voltage, wherein the second compensation capacitor generates the second intermediate current at the second node according to the input voltage.

27. The amplifier circuit of claim 26, wherein the current buffer is for use in an amplifier circuit, wherein the amplifier circuit is configured to operably amplify an intermediate amplification signal at an intermediate node within the amplifier circuit to generate an amplified output signal at an amplification output terminal of the amplifier circuit, wherein an absolute value of a gain between the amplified output signal and the intermediate amplification signal is larger than 1;
wherein the amplification output terminal is coupled to the input node of the current buffer, the amplified output signal corresponds to the input voltage of the current buffer, the intermediate node is coupled to the first node of the current buffer, the intermediate amplification signal is generated according to the output current of the current buffer, thereby the current buffer is configured as Miller compensation for the amplifier circuit, and the first zero of the current buffer is configured to compensate for at least one pole of the amplifier circuit, such that the amplifier circuit has sufficient phase margin.
